(19) United States
(12) Patent Application Publication
(10) Pub. No.: US 2013/0014898 A1
(43) Pub. Date: Jan. 17, 2013

(54) PLASMA BREAKERS AND METHODS THEREFOR

(71) Applicant: Hariharakeshava Sarpangala Hegde, Fremont, CA (US)

(72) Inventor: Hariharakeshava Sarpangala Hegde, Fremont, CA (US)

(21) Appl. No.: 13/180,475

(22) Filed: Jul. 11, 2011

(51) Int. Cl. C23C 16/505; H01L 21/3065; C23C 16/50

(52) U.S. Cl. 156/345.48; 118/723 R; 118/723 I; 156/345.1

(57) ABSTRACT

A plasma processing system comprising of a plasma source having a source enclosure for generating plasma is provided. The plasma processing system also includes a plasma breaker disposed inside the source enclosure. The plasma breaker has a plurality of trenches wherein at least one of the trenches has a sufficiently high aspect ratio such that materials deposited inside the source enclosure covers a surface of the plasma breaker without being deposited at a bottom of at least one of the trenches for at least a time period (t).

### BACKGROUND OF THE INVENTION

In remote RF (radio frequency) inductively coupled plasma (ICP) deposition or etch applications, a plasma is typically formed in the RF ICP source and directed toward the target or the wafer for deposition or etching respectively. For example, a remote RF ICP source-based deposition system may employ one or more steering magnets to steer the plasma that is formed inside the RF ICP source toward a target. Ions from the plasma sputter material off the target for deposition onto a wafer for example.

While processing metallic targets, the remote plasma-based deposition system may sputter the target and cause the sputter material to be deposited everywhere, including on the interior surface of the RF ICP source itself. With respect to FIG. 1, for example, there is shown a remote dual RF ICP source-based arrangement 102, which includes two RF ICP sources 104 and 106. In the example FIG. 1, RF ICP sources 104 and 106 are identical although neither this (nor the fact that there are two sources) is an absolute requirement. With respect to RF ICP source 104, there is shown source enclosure 108 within which plasma is generated via RF energy provided to RF coil 110. RF energy from RF coil 110 couples with gas(es) injected into source enclosure 108 to ignite and form a plasma therein. The ions from the plasma are then steered toward target 120 via one or more magnets. In the example of FIG. 1, two magnets 122 and 124 are shown although the number of magnets may vary and in some cases no magnets may be necessary.

As discussed earlier, ions from RF ICP source 104 sputter material off target 120 for deposition on wafer 150. If target 120 is made of a metallic material, such as aluminum, target material deposition inside on the interior surface of source enclosure 108 of RF ICP source 104 may interfere with the RF coupling of the RF energy from RF coil 110 to the plasma that is generated inside source enclosure 108. This is because the metallic surface formed by the sputtered metallic target material on the insulating inner surface of source enclosure 108 facilitates the formation of eddy current, which flows counter to the direction of the electric field generated by the RF coil. Consequently, less of the electric field generated by RF coil 110 is able to penetrate through the deposited metallic surface to couple with the plasma in source enclosure 108. When this happens, the plasma density at the target 120 is reduced, which affects the deposition rate on wafer 150.

Further, since the deposition of the sputtered material on the interior surface of source enclosure 108 occurs over time, the change in the target sputter rate also varies over time. To compensate for the reduced plasma density at the target (which affects the deposition rate on the wafer), some have attempted to monitor the target current in order to compensate for the reduced plasma density at the target by increasing the amount of RF power supplied to RF coil 110. Under this compensation scheme, an increasingly higher amount of RF power is required to roughly maintain the same deposition rate on wafer 150 over time.

However, this compensation scheme is less than satisfactory in some applications since the rate of sputtered material deposition on the interior surface of source enclosure 108 depends on many factors, including parameter settings of previous processing cycles, the composition of target 120, and other system settings such that compensation is always roughly approximate and is often inadequate to maintain a constant and predictable sputter rate for target 120 and a constant and predictable deposition rate on wafer 150.

The undesirable sputtered material deposition on the inner surface of the plasma enclosure is particularly troublesome in reactive sputter deposition of some metal oxides, such as Aluminum Oxide, or Titanium Oxide, or Chromium Oxide. In these reactive depositions, the pure metal target is sputtered and the oxide is formed at the wafer by introducing Oxygen at the proximity of the wafer. These reactive processes suffer from Target poisoning conditions, where the target current is strongly influenced by the purity of target surface. The deposition rate at the wafer is no longer proportional to the target current, due to the target poisoning. In such cases, it is important to periodically condition the target surface in a purely inert environment without any Oxygen in the process. To elaborate, as the target is utilized over many processing cycles, the surface of the target may become oxidized. In this case, it is a common practice to condition the target for a few minutes. (up to 30 minutes after depositing oxides on a full cassette of wafers, for example) to expose the metallic target material for further sputtering deposition. This conditioning process typically occurs in an inert gas environment in order to prevent the target surface from being oxidized again.

During this time when the target is sputtered in an inert gas environment to recondition the target, metallic sputtered aluminum (or Titanium, or Chromium) material may be deposited on the interior surface of source enclosure 108 of RF ICP source 104. This deposited non-oxidized aluminum material (due to the use of inert gas surrounding the target during target conditioning) can facilitate the formation of the aforementioned eddy current, thereby causing RF shunting which impacts the sputter rate of the target and the deposition rate on the wafer.

The problem is not limited only to deposition systems. In etch systems where the wafer has a metallic layer thereon that is being etched, the etched metallic material may be redeposited on the interior surface of the ion source and may also facilitate the formation of the aforementioned eddy current, which shunts the RF and reduces the energy coupling to the plasma inside the plasma source. When this happens, the etch rate on the wafer is reduced over time, which requires compensation and/or negatively affects the etch rate on the wafer.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows an example of a reactive deposition system schematic. Here remote RFICP source generated plasma is steered magnetically to a metallic target and oxide film is formed on wafer with Oxygen introduced in wafer proximity.

FIG. 2A shows a cutaway view of a typical prior art RF ICP source.

FIG. 2B shows, in accordance with an embodiment of the present invention, the RF ICP source of FIG. 2A with the addition of a plasma breaker.

FIGS. 2C and 2D show, in accordance with embodiments of the present invention, an example of the construction of typical plasma breakers.

FIG. 2E is another example, in accordance with an embodiment of the present invention, of an embodiment of the inventive plasma breaker wherein the rod is in the form of a rectangular rod.

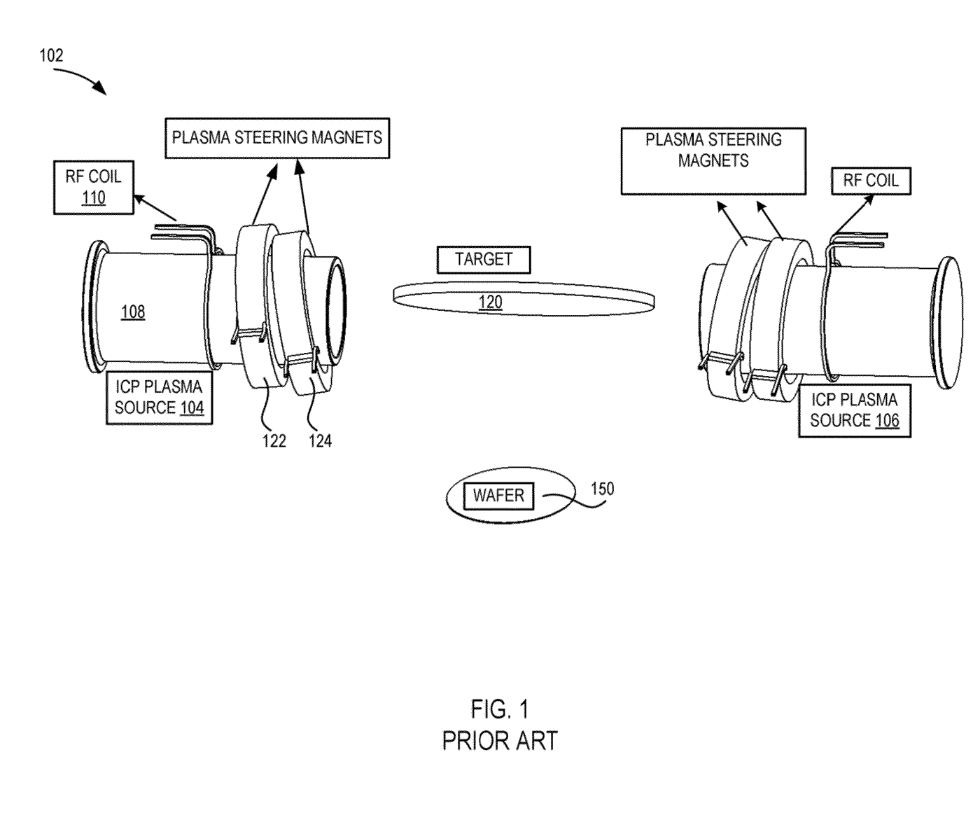

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Embodiments of the invention relate to an arrangement for attenuating the effect of eddy currents formed in the layer of deposited metallic material on the inner surface(s) of the ICP source enclosure. In one or more embodiments, one or more plasma breakers are provided, which prevent the formation of eddy currents in the layer of deposited metal material. Generally speaking, a plasma breaker is a rod-like structure that at least spans the length of the coil employed to couple RF energy to the plasma. The rod-like structure has thereon longitudinal grooves that span at least a substantial portion of the length of the rod-like structure. These longitudinal grooves are essentially high aspect ratio grooves (meaning they are much deeper than they are wide). The width and depth of these grooves are dimensioned such that the deposited material cannot easily reach the bottom of the groove.

When the sputter/etch metallic material is unable to reach the bottom of the longitudinal trenches, the absence of the sputter/etch metal material at the bottom of the trench represent breaks in the eddy current, thereby preventing the eddy current from having a complete (or closed) loop. In this manner, the rod-like plasma breaker effectively “breaks” the eddy current Thus, RF shunt is substantially reduced and/or eliminated, rendering it immaterial that there is metal material deposition on the interior surface of the ICP source. As long as the eddy current is unable to form a closed loop, eddy current attenuation is achieved.

It is envisioned that in one or more embodiments, the RF breaker(s) may be replaced occasionally in order to ensure that the sputter/etch material does not fill the trenches. As long as there are physical breaks in the current path of the eddy current in the deposited metal layer, the formed eddy current cannot complete its loop to interfere with the RF coupling process.

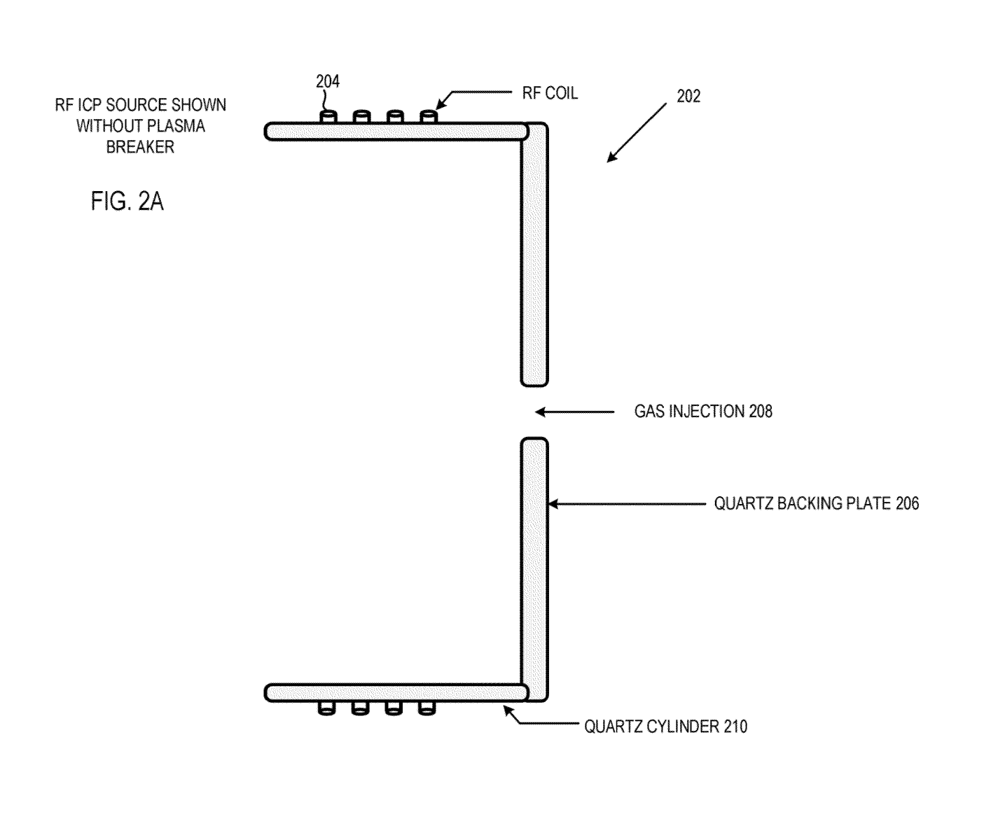

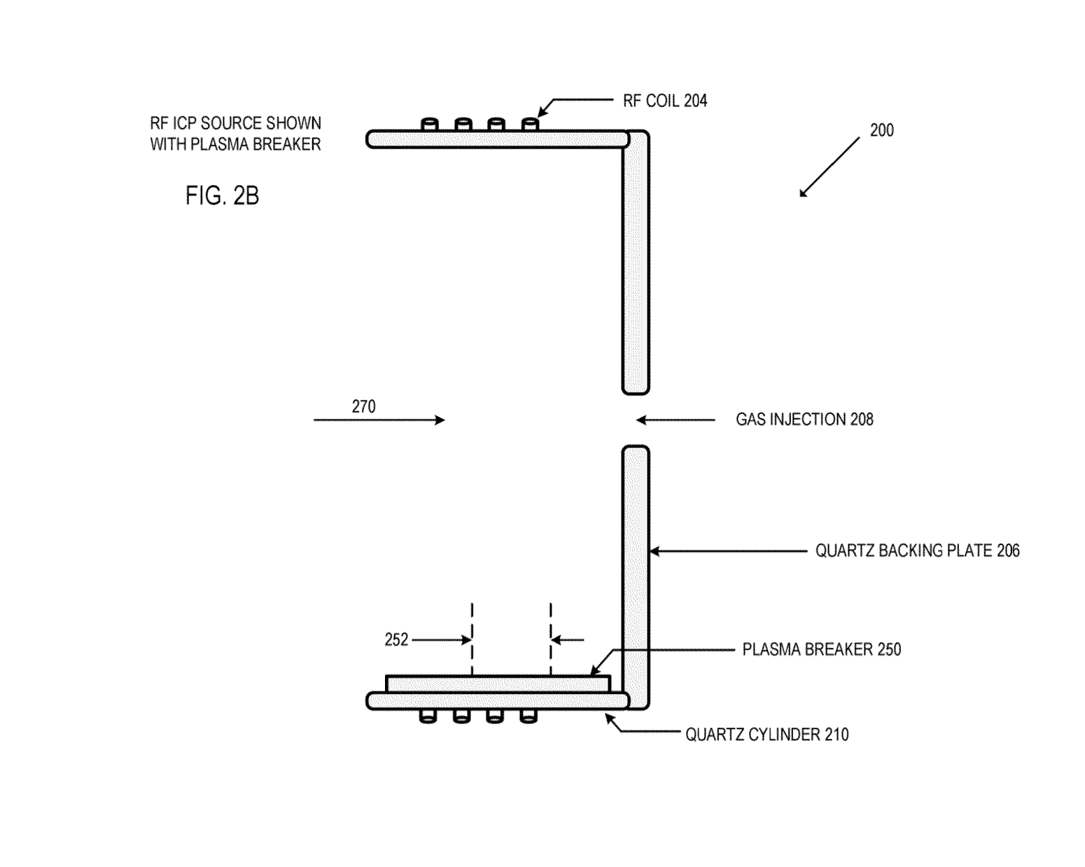

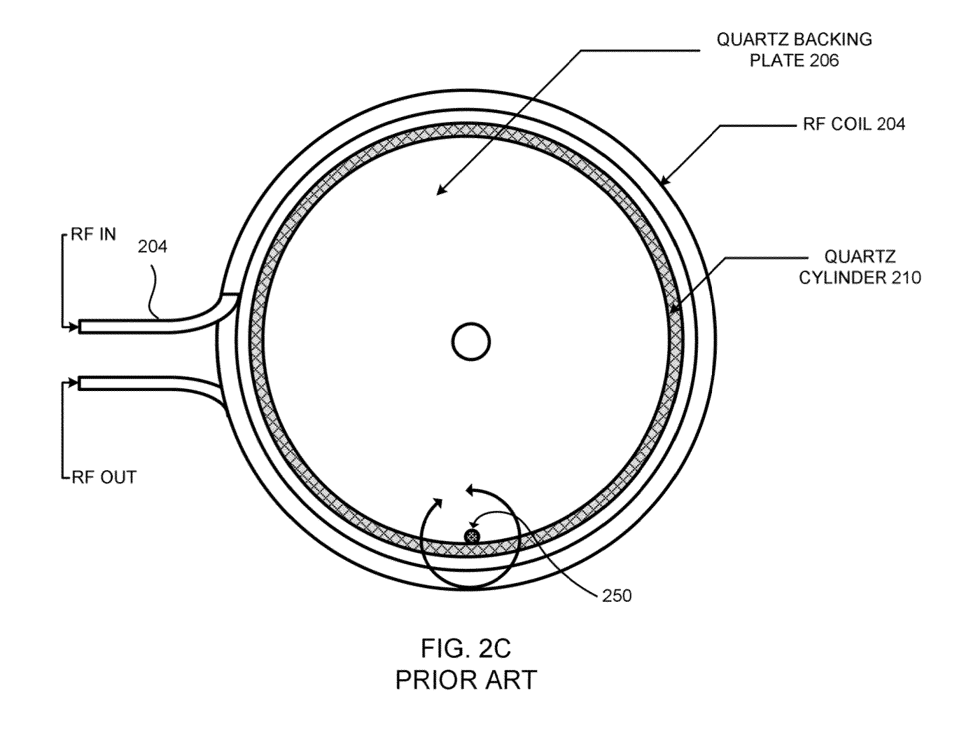

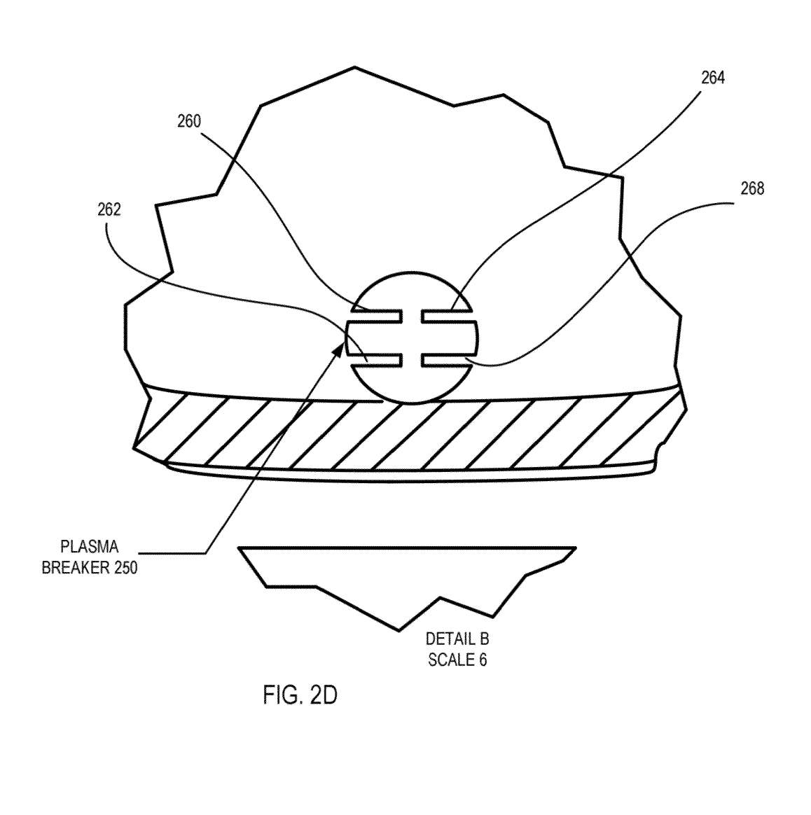

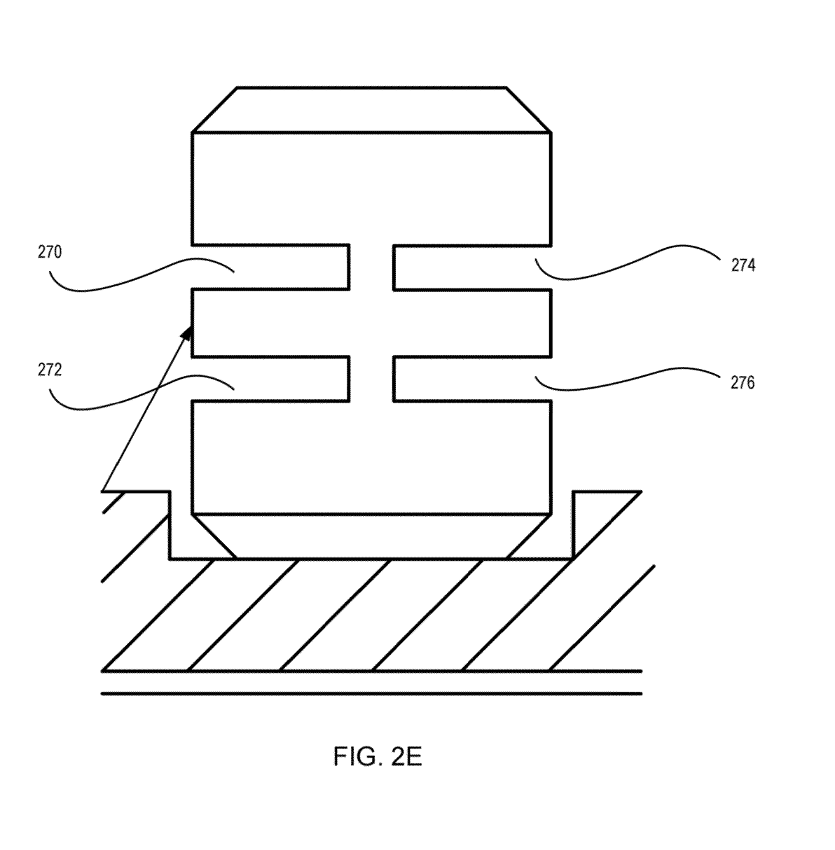

The features and advantages of various embodiments of the invention may be better understood with reference to the figures and discussions that follow. FIG. 2A shows a cutaway view of a typical prior art RF ICP source in which source enclosure 202 is used to enclose the plasma generated from RF energy provided to RF coil 204. Source enclosure 202 includes a typically cylindrical body 210 made out of a suitable material such as quartz. A quartz backing plate 206 is position at one end of cylindrical body 210 in order to substantially enclose one end of the cylindrical body 210. One or more gas injection ports 208 may be provided through quartz backing plate 206 or through cylindrical body 210 in order to permit the process gas to be injected into the interior region of source enclosure 202 within which the process gas is turned into plasma. The arrangement of FIG. 2A is fairly typical thus far and may include other components which are also conventional.

FIG. 2B shows, in accordance with an embodiment of the present invention, the RF ICP source of FIG. 2A with the addition of a plasma breaker 250. As discussed, plasma breaker 250 is a rod-like structure that at least spans the length of coil 204. In FIG. 2B, this length is denoted by reference number 252. In other words, plasma break 250 at least straddles RF coil 204 and is longer than the length 252 of RF coil 204.

FIGS. 2C and 2D show, in accordance with embodiments of the present invention, an example of the construction of typical plasma breakers. FIG. 2C is a view along the longitudinal axis of the RF ICP source 200 of FIG. 2B. The view in FIG. 2C is taken in the direction of arrow 270 in FIG. 2B. In FIG. 2C, RF coil 204 is again shown disposed around quartz cylindrical body 210. Plasma breaker 250 is shown disposed on or adjacent to the inner surface of cylindrical body 210.

FIG. 2D shows the construction of plasma breaker 250 in greater detail. As shown in FIG. 2D, plasma breaker 250 is implemented in the form of a rod-like structure (a substantially circular rod in the example of FIG. 2D although other rod shapes may also be employed) that spans at least the length of the RF coil and preferably spans the length of the ICP source along the longitudinal axis direction such that it substantially covers the portion of the inner surface adjacent to the RF ICP source where eddy current may be expected to be formed in the anticipated deposited layer.

In an alternate embodiment, plasma breaker 250 spans the entire length of the cylindrical body, i.e., from the quartz backing plate to the opening of the ICP source where ion is emitted toward the target or toward the wafer. In another alternate embodiment, this plasma breaker only covers a portion of the entire distance between the backing plate and the opening of the RF ICP source.

Longitudinal grooves 260, 262, 264 and 268 are shown disposed in plasma breaker 250. As mentioned, these longitudinal grooves 260, 262, 264, 268 are narrow and deep high aspect ratio trenches such that material deposited on the inner surface of cylindrical body 210 and on the outer surface of plasma breaker 250 itself does not penetrate to the bottom of the trenches. In an example, a typical dimension of a groove width may be in the 0.5 mm range whereas the depth may be about a few millimeters. Accordingly, the deposited material layer is interrupted at least at the bottom of the trench, thereby preventing eddy current from having a closed circuit. In this manner, eddy current is disrupted and RF shunting is substantially avoided.

In the example of FIG. 2D, four trenches are shown although the number of trenches may vary anywhere from one to N where N is an integer. Further, the trenches do not need to be identical and they may be staggered if desired. Still further, the trenches do not have to run the entire length of the rod-like structure (although it may be preferable in some situations that the trench spans the entire length of the rod).

One or multiple plasma breakers may be provided for each cylindrical enclosure employed to generate the ICP plasma. In the example of FIG. 2C, only a single plasma breaker is provided although there's no limitation to the number of plasma breakers that may be provided inside the cylindrical body.

FIG. 2E is another example, in accordance with an embodiment of the present invention, of an embodiment of the inventive plasma breaker wherein the rod is in the form of a rectangular rod. Similar to the situation if FIG. 2D, a plurality of trenches 270, 272, 274 and 276 are provided although, as mentioned, the number of trenches may vary. The plasma breaker of FIG. 2E is shown at least partially counter-sunk into the inner surface of cylindrical body 210 although this counter-sinking feature is not absolutely necessary.

As can be appreciated from the foregoing, embodiments of the invention substantially eliminate the formation of eddy currents in the layer of deposited metallic material on the inner surface of the insulating cylindrical body of the RF ICP source. Electrically speaking, the presence of the plasma breaker(s) with associated deep aspect ratio trench(es) thereon, prevents the deposited material from forming a continuous current path, thereby breaking the eddy current and reducing the RF shunting. With the plasma breaker in place, RF coupling between the RF coil and the plasma inside the RF ICA source is not unduly attenuated or reduced by the presence and/or gradual deposition of the sputtered/etched material on the inner surface of the RF ICP source. Accordingly, complicated or inexact compensation is not necessary, and the sputter deposition rate or etch rate may be kept more predictable and controllable over time.

While this invention has been described in terms of several preferred embodiments, there are alterations, permutations, and equivalents, which fall within the scope of this invention. It should also be noted that there are many alternative ways of implementing the methods and apparatuses of the present invention. Although various examples are provided herein, it is intended that these examples be illustrative and not limiting with respect to the invention. Also, the title is provided herein for convenience and should not be used to construe the scope of the claims herein. If the term “set” is employed herein, such term is intended to have its commonly understood mathematical meaning to cover zero, one, or more than one member.

What is claimed is:

1. A plasma processing system, comprising:
a plasma source having a source enclosure for generating a plasma therein;
a plasma breaker disposed inside said source enclosure, said plasma breaker having a plurality of trenches therein, wherein at least one of said trenches has a sufficiently high aspect ratio such that materials deposited inside said source enclosure covers a surface of said plasma breaker without being deposited at a bottom of said at least one of said trenches for at least a time period (t).

2. The plasma processing system of claim 1 wherein said plasma source represents a RF power source.

3. The plasma processing system of claim 1 wherein said plasma is employed for sputter deposition.

4. The plasma processing system of claim 1 wherein said plasma source is an inductively coupled plasma source.

5. The plasma processing system of claim 2 wherein a length of said plasma breaker exceeds a length of an RF coil employed to generate plasma in said plasma source.

6. The plasma processing system of claim 1 wherein said plasma breaker has a generally cylindrical rod shape.

7. The plasma processing system of claim 1 wherein said plasma breaker has a rod shape.

8. The plasma processing system of claim 1 wherein said plasma breaker has a rectangular rod shape.

9. The plasma processing system of claim 1 wherein said plasma breaker is in physical contact with an interior surface of said source enclosure.

10. The plasma processing system of claim 9 wherein said plasma breaker is at least partially counter-sunk into said interior surface of said source enclosure.

11. The plasma processing system of claim 2 wherein a length of said at least one of said trenches exceeds a length of an RF coil employed to generate plasma in said plasma source.

12. The plasma processing system of claim 11 wherein said at least one of said trenches is different from another trench of said plurality of trenches.

13. A plasma processing system, comprising:
a plasma source having a source enclosure for generating a plasma therein;
a plurality of plasma breakers disposed inside said source enclosure, wherein each plasma breaker of said plurality of plasma breakers having a plurality of trenches therein, wherein at least one of said trenches has a sufficiently high aspect ratio such that materials deposited inside said source enclosure covers a surface of said each plasma breaker without being deposited at a bottom of said at least one of said trenches for at least a time period (t).

14. The plasma processing system of claim 13 wherein said plasma source represents a RF power source.

15. The plasma processing system of claim 13 wherein said plasma is employed for sputter deposition.

16. The plasma processing system of claim 13 wherein said plasma source is an inductively coupled plasma source.

17. The plasma processing system of claim 14 wherein a length of said each plasma breaker exceeds a length of an RF coil employed to generate plasma in said plasma source.

18. The plasma processing system of claim 13 wherein said each plasma breaker has a generally cylindrical rod shape.

19. The plasma processing system of claim 13 wherein said each plasma breaker is in physical contact with an interior surface of said source enclosure.

20. The plasma processing system of claim 14 wherein a length of said at least one of said trenches exceeds a length of an RF coil employed to generate plasma in said plasma source.
